(19) United States
(12) Patent Application Publication
(10) Pub. No.: US 2025/0331126 A1
(43) Pub. Date: Oct. 23, 2025

(54) COOLING DEVICE FOR COOLING AN ELECTRICAL AND/OR ELECTRONIC ASSEMBLY

(71) Applicant: Robert Bosch GmbH, Stuttgart (DE)

(72) Inventors: Maik Paehrisch, Reutlingen (DE); Max Florian Beck, Vaihingen An Der Enz (DE); Tobias Hoppe, Kuppenheim (DE)

(21) Appl. No.: 18/870,778

(22) PCT Filed: May 25, 2023
(86) PCT No.: PCT/EP2023/064107

§ 371 Date: Dec. 2, 2024

(30) Foreign Application Priority Data
Jun. 7, 2022 (DE) 10 2022 205 733.3

(51) Int. Cl. H05K 7/20

(52) U.S. Cl. CPC H05K 7/20145; H05K 7/20272

(57) ABSTRACT

The invention relates to a cooling device for cooling an electrical and/or electronic assembly (2), said cooling device comprising: a top plate (3) and a bottom plate (4), the bottom plate (4) being a deep-drawn component comprising a depression (40), the top plate (3) and the bottom plate (4) being arranged such that, due to the depression (40), a cooling channel (5) is formed between the top plate (3) and the bottom plate (4), the top plate (3) and the bottom plate (4) being connected to one another at a contact region (8) outside the depression (40), it being possible for a cooling fluid flow of a cooling fluid to flow through the cooling channel (5), the cooling device (1) further comprising at least one turbulator (6) arranged inside the depression (40) of the cooling channel (5), the turbulator (6) adjoining a bottom surface (44) in the depression (40) of the bottom plate (4) and the bottom surface (44) facing the top plate (3). According to the invention, the bottom plate (4) comprises an embossment (7) in a bending region (43) on the edge of the bottom surface (44).

### BACKGROUND

The present invention relates to a cooling device for the cooling of an electrical and/or electronic assembly, as well as an electronic arrangement.

Power modules, such as inverter structures or converter structures, are used in hybrid vehicles or electric vehicles. For example, inverters that provide phase currents to the electric machine are used to operate an electric machine. The power modules can, for example, comprise a support substrate with conductor tracks on which, for example, power semiconductors are arranged which, together with the support substrate, form an electronic unit. During operation, heat is generated by the electrical unit, which must be dissipated to a cooling device. For this purpose, the electronic unit is thermally connected to the cooling device. It is known to provide cooling devices with cooling channels in which a cooling fluid can flow to dissipate the heat from the cooling element. What are referred to as turbulators can be provided in the cooling channels and ensure better heat dissipation from the cooling device to the cooling fluid flowing through the cooling device. The turbulators generate turbulent flows and increase the cooling surface.

### SUMMARY

Proposed according to the invention is a cooling device for cooling an electrical and/or electronic assembly. The cooling device comprises a top plate and a bottom plate, the bottom plate being a deep-drawn component comprising a depression, the top plate and the bottom plate being arranged such that, due to the depression, a cooling channel is formed between the top plate and the bottom plate, the top plate and the bottom plate being connected to one another at a contact region outside the depression, it being possible for a cooling fluid flow of a cooling fluid to flow through the cooling channel, the cooling device further comprising at least one turbulator arranged inside the depression of the cooling channel, the turbulator adjoining a bottom surface in the depression of the bottom plate and the bottom surface facing the top plate. The bottom plate comprises an embossment in a bending region on the edge of the bottom surface.

Compared to the prior art, the cooling device having the features of the disclosure features a particularly high degree of efficiency with regard to cooling the electrical and/or electronic assembly being cooled. The embossment can block or severely restrict a bypass flow through a bypass region on the edge of the turbulator. The embossment enlarges the depression in the bottom plate. By embossing the bending region on the edge of the bottom surface, the depression in the bending region on the edge of the bottom surface is enlarged. The edge of the bottom surface which is rounded by deep-drawing the bottom plate loses its roundness due to the embossment. The turbulator can therefore fill a larger region in the depression, and thus in the cooling channel. The deep-drawn bottom plate is thus subsequently adapted to the shape of the turbulator in order to minimize the distance between the turbulator and the bottom plate, and thus that of the bypass flow. The turbulator thereby projects into the embossment and fills an advantageously large region in the cooling channel. As a result, a bypass region adjacent to the turbulator is advantageously reduced. A bypass flow through a bypass region on the edge of the turbulator can thus be blocked or severely restricted.

According to one advantageous exemplary embodiment, it is provided that a radius in the bending region of the bottom plate on the edge of the bottom surface is reduced by embossment. The radius of the bending region to the edge of the bottom surface inside the cooling channel can thus be advantageously small, and the bending region can be designed to be substantially rectangular, due to the embossment inside the cooling channel. The turbulator can thus advantageously project far into the bending region and the bypass flow in the bypass area can be advantageously reduced.

According to one advantageous exemplary embodiment, it is provided that a particularly rectangular shape is formed in the bending region on the edge of the bottom surface by the embossment. The turbulator, which itself comprises, e.g., a bend in a region facing the bending region of the bottom plate can thus advantageously project far into the embossment and the bypass region.

According to one advantageous exemplary embodiment, it is provided that solder is arranged between the turbulator and the bottom plate in the embossment, and the turbulator is connected to the bottom plate in the embossment by means of the solder. The solder can advantageously easily be drawn into the minimized intermediate space between the turbulator and the base plate in the embossment by means of capillary action. A bypass flow between the turbulator and the bottom plate in the embossment can thus be advantageously reduced.

The cooling device according to one of the preceding claims is characterized by an intermediate space between the turbulator and the bottom plate in the embossment is completely filled with solder. The region between the turbulator and the bottom region in the embossment is thus completely sealed and blocked for a bypass flow of the cooling fluid past the turbulator. The solder can advantageously easily be drawn into the intermediate space by means of capillary action.

The cooling device according to one of the preceding claims is characterized in that, in a region where the top plate is at a distance from the bottom plate, solder is arranged between the top plate and the bottom plate, and/or solder is arranged between the turbulator and the bottom plate in a region outside the embossment. Therefore, the bypass region in the cooling channel is further sealed by additional solder in the cooling device, which is not used, for example, for connecting the bottom plate, top plate and turbulator to one another. As a result, more cooling fluid flows through the turbulator and less past the turbulator so that the cooling device has increased cooling efficiency for cooling the electrical and/or electronic assembly. The solder can also advantageously be simply drawn into the corresponding intermediate spaces by means of capillary action.

The cooling device according to one of the preceding claims is characterized by the turbulator being made of bent sheet metal, whereby the sheet metal comprises a bend with a radius of the turbulator in a region facing the bending region of the bottom plate. Such a turbulator can advantageously be produced simply by cutting and forming a metal sheet, for example by punching and bending, for example in the same way as the top plate metal and the bottom plate.

According to one advantageous exemplary embodiment, it is provided that a radius in the bending region of the bottom plate on the edge of the bottom surface is smaller than the radius of the turbulator in the region of the turbulator facing the bending region of the bottom plate. The turbulator can thus advantageously project far into the embossment and be in contact with the bottom surface and a side region of the bottom plate, and/or be attached to it, for example soldered to it.

The cooling device according to one of the preceding claims is characterized by the embossment on the edge of the bottom surface being recessed opposite the bottom surface. A notch is thus punched into the edge of the bottom surface. As a result, overlaps between the parts can be prevent, and it can be ensured that the turbulator is able to project into the embossment. Furthermore, an enlarged intermediate space between the turbulator and bottom plate can thus be formed in the embossment and be filled with solder in an advantageous manner.

The cooling device can further be comprised of an electronic arrangement, the electronic arrangement further comprising at least one electrical and/or electronic assembly to be cooled, the electronic component being arranged on the top plate or on the bottom plate.

### BRIEF DESCRIPTION OF THE DRAWINGS

Exemplary embodiments of the invention are shown in the drawings and explained in more detail in the subsequent description. Shown are:

FIG. 1 a cross-section through an exemplary embodiment of an electronic arrangement comprising a cooling device,

FIG. 2 a magnified section of the exemplary embodiment of the electronic arrangement comprising the cooling device,

FIG. 3 a cut-out from a second exemplary embodiment of the electronic arrangement.

### DETAILED DESCRIPTION

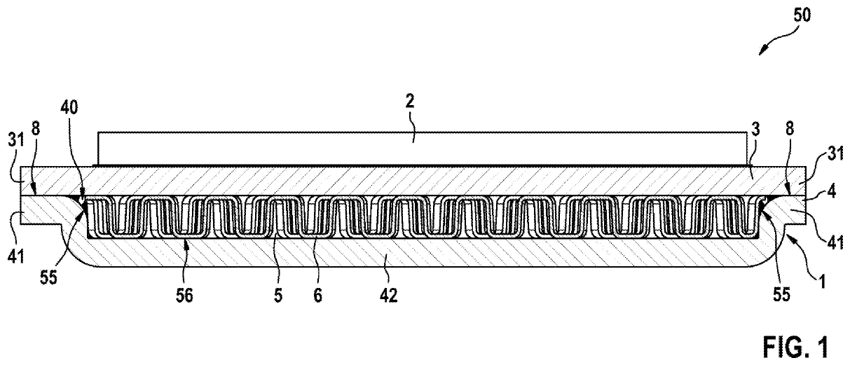

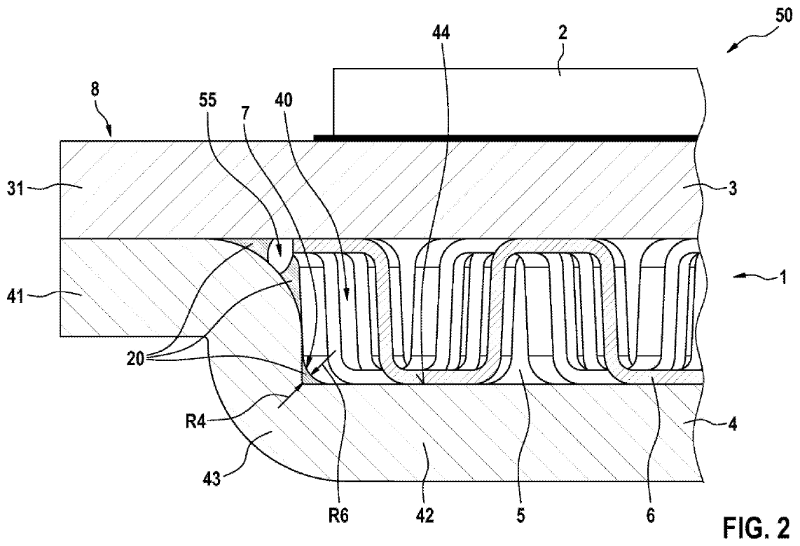

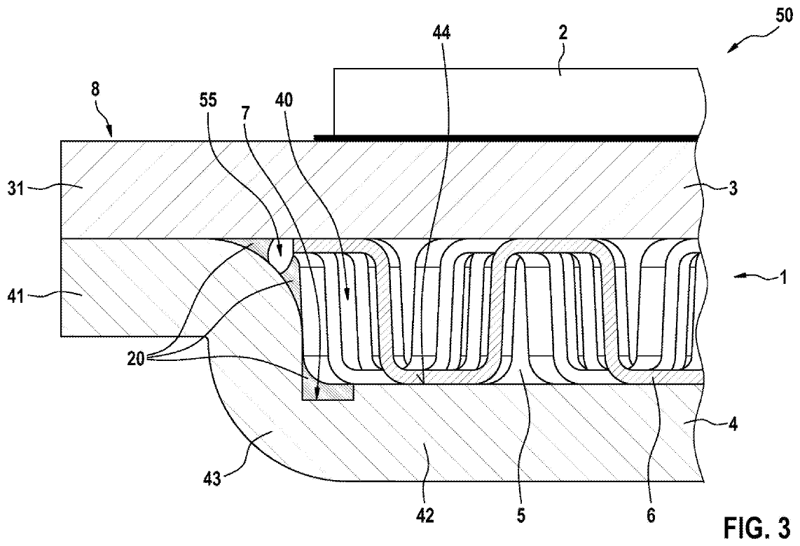

FIG. 1 shows a sectional view through an exemplary embodiment of an electronic arrangement 50. The electronic arrangement 50 comprises a cooling device 1 and an electrical and/or electronic assembly on the cooling device 1. FIG. 2 shows an enlarged detail of the exemplary embodiment of the cooling device 1 of FIG. 1. FIG. 3 shows a second exemplary embodiment of the cooling device 1.

The cooling device 1 is used to cool the electrical and/or electronic assembly 2, for example a power circuit. These can be, for example, power circuits, such as inverter structures or converter structures, of hybrid vehicles or electric vehicles. For example, the electrical and/or electronic assembly 2 can be designed as a power module and comprise, for example, a support substrate having traces on which, for example, power semiconductors are arranged to form an electronic unit together with the support substrate. During operation, heat is generated by the electrical and/or electronic assembly 2 and must be dissipated to a cooling device 1. For this purpose, the electrical and/or electronic assembly 2 is arranged on the cooling device 1, for example on a contact surface of a top plate 3 or a bottom plate 4. One or multiple layers can be arranged between the cooling device 1 and the electrical and/or electronic assembly 2 for fastening and thermally connecting the electrical and/or electronic assembly 2 to the cooling element 1. For example, a copper coating can be provided on the contact surface of the top plate 3 facing the electrical and/or electronic assembly 2. On the cooling device 1, a plurality of electrical and/or electronic assemblies 2 can also be arranged, for example, next to one another, on the top plate 3 of the cooling device 1. Thus, each of the electrical and/or electronic assemblies 2 is thermally connected to the cooling device 1 and attached to it.

The bottom plate 4 and the top plate 3 form outer walls of the cooling device 1. The bottom plate 4 forms a bottom side of the cooling device 1. The top plate 3 forms a top side of the cooling device 1. The bottom plate 4 and the top plate 3 can, for example, be made of a material with high thermal conductivity, such as a metal like aluminum. The bottom plate 4 and the top plate 3 are shaped from metal sheets. The bottom plate 4 and/or the top plate 3 each have a constant thickness, for example. The bottom plate 4 and the top plate 3 can have the same thickness, for example. However, the bottom plate 4 and the top plate 3 can also have different thicknesses.

A depression 40 is formed in the bottom plate 4. The bottom plate 4 is therefore essentially trough-shaped. The top plate 3 is arranged on the bottom plate 4 such that the depression 40 in the bottom plate 4 is covered by the top plate 3. The bottom plate 4 and the top plate 3 are arranged together so that a cooling channel 5 is formed between the bottom plate 4 and top plate 3 by the depression 40. The cooling channel 5 extends between the bottom plate 4 and the top plate 3. The bottom plate 4 and the top plate 3 form walls delimiting the cooling channel 5. The bottom plate 4 is designed as a deep-drawn part. An edge 41 of the bottom plate 4, which is formed in a plane, for example, is connected to an edge 31 of the top plate 3. The region in which the bottom plate 4 is connected to the top plate 3 is referred to as the contact region 8. The edge 41 of the bottom plate 4 circumferentially circumscribes the depression 40 in the bottom plate 4. The edge 41 of the bottom plate 4 rests on the edge 31 of the top plate 3, for example, either directly or with the interposition of an intermediate layer. The edge 41 of the bottom plate 4 is firmly connected, in particular soldered, to the edge 31 of the top plate 3. The edge 41 of the bottom plate 4 can be connected, in particular soldered, to the edge 31 of the top plate 3 directly or with the interposition of one or more intermediate layers or intermediate elements. The edge 41 of the bottom plate 4 is connected to the edge 31 of the top plate 3 using a brazing process, for example. The edge 41 of the bottom plate 4 is connected, in particular soldered, to the edge 31 of the top plate 3 in a circumferential manner.

In the region of the depression 40, the bottom plate 4 is at a distance from the top plate 3 such that a cavity, through which flow can take place and in which the cooling channel 5 extends, is formed between the bottom plate 4 and the top plate 3. As in this exemplary embodiment, the edge 41 of the bottom plate 40 can extend flat in a first plane. Furthermore, a portion of the sheet metal 42 of the bottom plate 40, which forms, for example, a bottom of the depression 40, can extend level in a second plane, which is in particular parallel to the first plane. The edge 41 of the bottom plate 40 and the portion of sheet metal 42 of the bottom plate 4 are therefore each arranged level and parallel to each other. The top plate 3 can, e.g., be designed as a level or also as a deep-drawn. The depression 40, and thus the cooling channel 5, can, at least in portions having a rectangular shape in particular, be elongated with respect to a bottom plate 4. At least portions of the cooling channel 5 extend along a longitudinal direction. Preferably, when viewed at a sheet metal plane of the top plate 3, the cooling channel 5 comprises an elongated region, in particular with rectangular geometry, which extends along the longitudinal direction, particularly defined by a straight line.

In the depression 40 of the bottom plate 4, the bottom plate 4 comprises an embossment 7. The bottom plate 4 is deformed on the embossment 7 by embossing. The bottom plate 4 is embossed on the interior of the depression. The embossment 7 is arranged on an edge of a bottom surface 44 of the bottom plate. The bottom surface 44 of the bottom plate 4 extends, in particular level, on the portion of sheet metal 42. The bottom surface 44 is a surface of the bottom plate 4 facing the cooling channel 5 and the top plate 3. The bottom surface 44 forms the bottom of the cooling channel 5 on the bottom plate 4. The embossment 7 is arranged at the edge of the bottom surface 44. The edge of the bottom surface 44 is the region in which the bottom plate 4 is deformed out of the plane of the bottom surface 44 in the direction of the top plate 3. The edge of the bottom surface 44 is arranged in a bending region 43 of the bottom plate 4, in which the bottom plate 4 is bent in the direction of the top plate 3 at the edge of the level portion of sheet metal 42. By embossment 7, a radius R4 of the bending region 43 inside the depression 40 is reduced as compared to the radius in the bend region 43 prior to embossment. The depression 40 and thus also the cooling channel 5 are enlarged in the bending region 43 by the embossment 7. The embossment 7 is embossed, for example, as a substantially rectangular corner into the bending region 43. At the edge of the bottom surface 44 a right-angled shape is, e.g., embossed into the bending region 43 of the bottom plate 4. The level portion of sheet metal 42 at the edge of the bottom surface 44 inside the depression 40 thus transitions at an angle, particularly at a right angle, to the bending region 43 of the bottom plate 4. The bottom surface 44 is arranged at an angle, particularly a substantially right angle, relative to a side surface that adjoins the bottom surface 44 in the interior of the depression 40. The radius R4 of the bend in the bottom plate 4 between the bottom surface 44 and the side surface is reduced by the embossment 7. An angle, in particular a substantially right angle, is embossed by the embossment 7 into the bending region 43 of the bottom plate 4. For example, as in the first exemplary embodiment of the cooling device 1 in FIG. 2, the embossment 7 can connect level to the bottom surface 44. The bottom surface 44 is thus widened by the embossment 7. However, the embossment 7 can also be recessed with respect to the bottom surface 44, e.g. designed as a notch on the edge of bottom surface 44. This is shown in the second exemplary embodiment of the cooling device 1 in FIG. 3.

An intermediate plate can, for example, be arranged between the top plate 3 and bottom plate 4. For example, such an intermediate plate can provide an additional distance to an upper side of the top plate 4 in order to adjust a height of the cooling channel 5. Alternatively, as in the exemplary embodiment shown in the drawings, the top plate 3 and the first portion of sheet metal 41 of the bottom plate 4 can also adjoin one another directly.

The cooling device 1 further comprises an inlet opening, not shown in the drawings, via which a cooling fluid can be supplied to the cooling channel 5 in the cooling device 1. Furthermore, the cooling device 1 comprises an outlet opening, through which the cooling fluid can flow out of the cooling channel 5 and the cooling device 1. The cooling fluid can, e.g., be water. The inlet opening and/or the outlet opening can, for example, be formed by openings in the depression 40 of the bottom plate 4. The openings can be, for example, apertures in the bottom plate 4. A feed nozzle can, e.g., also be arranged or formed at the inlet opening. An outlet nozzle can likewise be arranged or formed at the outlet opening. A cooling fluid flow of a cooling fluid can flow through the cooling channel 5 from the inlet opening to the outlet opening. A cooling fluid can flow into the cooling channel 5 through the inlet opening of the cooling device 1 and flow out of the cooling channel 5 of the cooling device 1 through the outlet opening of the cooling device 1. The cooling channel 5 is designed to feed cooling fluid through the cooling device 1. The cooling channel 5 in the cooling device 1 extends in the cooling device 1 from the inlet opening to the outlet opening. A cooling fluid flow of a cooling fluid can flow through the cooling channel 5 in the longitudinal direction from the inlet opening to the outlet opening.

The cooling device 1 further comprises at least one turbulator 6. The turbulator 6 is arranged within the cooling channel 5. The turbulator 6 is arranged in a turbulator portion 56 of the cooling channel 5 extending along the longitudinal direction. The turbulator 6 is arranged between the top plate 3 and the bottom plate 4. The turbulator 6 can extend from the top plate 3 to the bottom plate 4 completely through the cooling channel 5. In particular, the turbulator 6 is in direct and/or indirect heat-conductive contact with the top plate 3 and the bottom plate 4. The turbulator 6 is attached to the top plate 3 and/or the bottom plate 4 using a brazing process, for example. The turbulator 6 adjoins the bottom surface 44 against the bottom plate 4 and/or is connected, in particular soldered, to the bottom surface 44. The turbulator 6 extends along the bottom surface 44. The turbulator 6 extends into the embossment 7. Cooling fluid flows through the turbulator 6 in the longitudinal direction parallel to, for example, the level top plate 3 and/or the portion of sheet metal 42 of the base plate 4. The turbulator 6 comprises a surface-enlarging, flow-guiding, and heat-transferring structure. The turbulator 6 is made of a metal with advantageous thermal conductivity, e.g. aluminum. The turbulator 6 can, e.g. also have a coating. The turbulator 6 can, e.g., be designed as a structured metal sheet. In order to achieve the highest possible cooling efficiency, as much of the flow cross-section of the cooling channel 5 between the bottom plate 4 and the top plate 3 as possible is filled by the turbulator 6. The turbulator 6 extends, e.g., in an essentially coplanar manner with respect to the top plate 3 and/or the portion of sheet metal 42 of the bottom plate 4 which is, e.g., designed to be flat. The turbulator 6 comprises, e.g., essentially the same surface area as the contact surface of the top plate 3 on which the electrical and/or electronic assembly 2 is arranged.

The turbulator 6 is, e.g., designed to be integral. The turbulator 6 is formed from a metal sheet, for example by cutting and deforming, in particular by punching and bending. The turbulator 6 is provided for generating turbulent flow in the cooling fluid. The turbulator 6 is structured for generating turbulent flow in the cooling fluid. A plurality of turbulence portions are, e.g., formed on the turbulator 6 and are arranged at an angle to the direction of flow, in particular the longitudinal direction, of the cooling fluid through the cooling channel 5. The turbulence portions are used to add turbulence to the cooling fluid flowing through the cooling channel 5. As a result, the heat is able to be dissipated particularly effectively. The turbulence portions can, e.g., be wave-like or jagged, or can be designed as periodically recurring ridges and/or depressions in the turbulator. The turbulence portions in the turbulator 6 can, e.g., be formed by cutting and forming, for example punching and bending, of the sheet metal from which the turbulator 6 is made.

To achieve a high level of cooling efficiency, as much of the flow cross-section of the cooling channel 5 as possible is covered by the turbulator 6. Given that the bottom plate 4 is a deep-drawn component, a demolding slope and radii on the edge of the depression 40 are required for the demolding process during deep drawing. These radii formed by deep-drawing are reduced by the embossment 7. The turbulator 6 is arranged below the electrical and/or electronic assembly 2. Bypass regions 55 are located on the edge of the cooling channel 5 to the side of the turbulator 6 and between the turbulator 6, the bottom plate 4 and the top plate 3. The bypass regions 55 are situated laterally adjacent to the electrical and/or electronic assembly 2 when viewed in the plane of the contact surface for the electrical and/or electronic assembly 2. The cooling channel 5 is designed to be tapered in the bypass region 55. No turbulence in the cooling fluid flow exists in the bypass regions 55. Due to the embossment 7, the turbulator 6 can fill an advantageously large portion of the cooling channel 5 with an unchanged extension from the bottom plate 4 to the top plate 3 into the embossment 7. In a region of the turbulator 6 facing the bending region 43 of the bottom plate 4, the turbulator 6 is bent and comprises a turbulator radius R6. The radius R4 denotes the radius of the bending region 43 on the edge of the bottom surface 44. The radius R6 of the turbulator 6 is larger than the radius R4 in the bending region 43 on the edge of the bottom surface 44. The turbulator 6 can thus project far into the embossment 7 and fill an advantageously large portion of the cooling channel 5.

As shown in the drawings, solder 20 can further be provided in the cooling device 1 at various locations. The solder 20 can be drawn into narrow locations spots in the cooling device 1 by means of capillary action, for example. The solder 20 can, e.g., be arranged between the turbulator 6 and the bottom plate 4 in the region of the embossment 7 and/or in the embossment 7. For example, intermediate spaces between the turbulator 6 and the bottom plate 4, in particular in the embossment 7, can in this case be filled with the solder 20. Regions in the cooling device 1 where the top plate 3 is at a distance from the bottom plate 4 can also be filled with solder 20. Furthermore, the solder 20 can also be arranged in regions between the bottom plate 4 and the turbulator 6 outside of the embossment 7. The solder 20 seals the locations where the cooling fluid can flow past the turbulator 6. As a result, a bypass flow of the cooling fluid past the turbulator 6 is reduced or prevented and the cooling efficiency of the electrical and/or electronic assembly 2 is improved by the cooling device 1.

Further exemplary embodiments and mixed forms of the illustrated exemplary embodiments are clearly also possible.

1. A cooling device for cooling an electrical and/or electronic assembly (2), said cooling device comprising: a top plate (3) and a bottom plate (4), wherein the bottom plate (4) is a deep-drawn component comprising a depression (40), wherein the top plate (3) and the bottom plate (4) are arranged such that, due to the depression (40), a cooling channel (5) is formed between the top plate (3) and the bottom plate (4), wherein the top plate (3) and the bottom plate (4) are connected to one another at a contact region (8) outside the depression (40), wherein it is possible for a cooling fluid flow of a cooling fluid to flow through the cooling channel (5), wherein the cooling device (1) further comprises at least one turbulator (6) arranged inside the depression (40) of the cooling channel (5), wherein the turbulator (6) adjoins a bottom surface (44) in the depression (40) of the bottom plate (4), wherein the bottom surface (44) faces the top plate (3),
wherein the bottom plate (4) comprises an embossment (7) in a bending region (43) on an edge of the bottom surface (44).

2. The cooling device according to claim 1, wherein a radius (R4) in the bending region (43) of the bottom plate (4) at the edge of the bottom surface (44) is reduced by the embossment (7).

3. The cooling device according to claim 1, wherein a rectangular shape is formed in the bending region (43) on the edge of the bottom surface (44) by the embossment (7).

4. The cooling device according to claim 1, wherein solder (20) is arranged between the turbulator (6) and the bottom plate (4) in the embossment (7), and the turbulator (6) is connected to the bottom plate in the embossment (7) by the solder (20).

5. The cooling device according to claim 1, wherein an intermediate space between the turbulator (6) and the bottom plate (4) in the embossment (7) is completely filled with solder (20).

6. The cooling device according to claim 1, wherein, in a region where the top plate (3) is at a distance from the bottom plate (4), solder (20) is arranged between the top plate (3) and the bottom plate (4), and/or solder (20) is arranged between the turbulator (6) and the bottom plate (4) in a region outside the embossment (7).

7. The cooling device according to claim 1, wherein the turbulator (6) is made of bent sheet metal, wherein the sheet metal comprises a bend with a radius (R6) of the turbulator (6) in a region of the turbulator (6) facing the bending region (43) of the bottom plate (4).

8. The cooling device according to claim 7, wherein a radius (R4) in the bending region (43) of the bottom plate (4) on the edge of the bottom surface (44) is smaller than the radius (R6) of the turbulator (6) in the region of the turbulator (6) facing the bending region (43) of the bottom plate (4).

9. The cooling device according to claim 1, wherein the embossment (7) on the edge of the bottom surface (44) is recessed opposite the bottom surface (44).

10. An electronic arrangement comprising:
a cooling device (1) according to claim 1, and
at least one electrical and/or electronic assembly (2) to be cooled, wherein the electrical and/or electronic assembly (2) is arranged on the top plate (3) or on the bottom plate (4).
